(19) United States
(12) Patent Application Publication
(10) Pub. No.: US 2011/0134690 A1
(43) Pub. Date: Jun. 9, 2011

(54) METHOD OF CONTROLLING A DRAM MEMORY CELL ON THE SeOI HAVING A SECOND CONTROL GATE BURIED UNDER THE INSULATING LAYER

(76) Inventors: Carlos Mazure, Bernin (FR); Richard Ferrant, Esquibien (FR)

(21) Appl. No.: 12/898,230

(22) Filed: Oct. 5, 2010

(30) Foreign Application Priority Data
Dec. 8, 2009 (FR) 0 958 749

(51) Int. Cl. G11C 11/34; H01L 29/772; H01L 21/336

(52) U.S. Cl. 365/184; 257/347; 438/151; 257/E29.242; 257/E21.411

(57) ABSTRACT

The invention relates to a method of controlling a DRAM memory cell of an FET transistor on a semiconductor-on-insulator substrate that includes a thin film of semiconductor material separated from a base substrate by an insulating layer or BOX layer, the transistor having a channel and two control gates, a front control gate being arranged on top of the channel and separated from the latter by a gate dielectric and a back control gate being arranged in the base substrate and separated from the channel by the insulating layer (BOX). In a cell programming operation, the front control gate and the back control gate are operated jointly by applying a first voltage to the front control gate and a second voltage to the back control gate, with the first voltage being lower in amplitude than the voltage needed to program the cell when no voltage is applied to the back control gate.

### FIELD OF THE INVENTION

The field of the invention is that of semiconductor devices, and more particularly that of memory devices comprising a plurality of memory cells.

The invention relates more particularly to a method of controlling a Dynamic Random Access Memory (DRAM) type memory cell on a semiconductor-on-insulator (SeOI) substrate.

### BACKGROUND OF THE INVENTION

A conventional DRAM memory cell is formed by the combination of a transistor and a capacitor to store charges.

More recently, a DRAM memory cell consisting of just a transistor has been proposed. This cell utilizes a floating channel effect to store the charges and requires no additional capacitor.

The floating channel DRAM cell is formed in a silicon-on-insulator SOI substrate having a thin film of silicon separated form the base substrate by a buried insulating layer, which is generally a layer of oxide designated “buried oxide layer” or BOX. A source region and a drain region are formed in the thin film on top of the BOX, a floating channel region separates the source and drain regions. A gate dielectric layer and a gate electrode are sequentially deposited on top of the floating channel, which isolates the channel region from the gate electrode. The drain region is connected to a bit line BL, the source region is connected to a source line SL and the gate electrode is connected to a word line WL.

The floating channel is electrically isolated by the BOX, the gate dielectric layer, the source region and the drain region, thereby creating a floating channel or body. Because of this isolation, the floating channel can store an electric charge.

In a data write operation in such a transistor, the floating body uses an impact ionization phenomenon to store charges, thereby modifying the threshold voltage of the transistor. In a data read operation, the quantity of current flowing between the source and the drain of the transistor then depends on the quantity of charges stored in the floating body.

The abovementioned DRAM cells offer the advantage of exhibiting a body effect which is characteristic of devices on SeOI and consists in storing charges, thereby modifying the threshold voltage of the transistor. In order to utilize this effect, it is necessary to apply an the threshold voltage of the transistor. In order to utilize this effect, it is necessary to apply an overvoltage to the gate electrode (via the word line WL). Thus, in order to be able to perform a logic 1 state write operation, a voltage greater than Vdd is typically applied, where Vdd corresponds to a nominal power supply voltage of the device. This overvoltage increases the current of the device and results in the impact ionization phenomenon which in turn creates the charges that will be stored under the channel, in the floating body.

It will be understood that the transistor is then stressed by this overvoltage. It is thus common practice to use relatively large transistors able to withstand such a stress.

Now, an ongoing objective in the field of application of the invention is that of miniaturization. It will therefore be understood that there is a need for a solution allowing for the use of smaller transistors in DRAM memory cells.

### SUMMARY OF THE INVENTION

The present invention relates to a met hod of controlling a DRAM memory cell comprising a FET transistor on a semiconductor-on-insulator substrate that comprises providing a FET transistor that comprising a base substrate, an isolating layer, a thin film of semiconductor material, wherein the thin film is separated from the base substrate by the isolating layer, a channel and two control gates, wherein there is a first control gate that is a front control gate and a second control gate that is a back control gate, a gate dielectric. A programmable cell is formed from the channel, two control gates and gate dielectric by arranging the front control gate on top of the channel separated from the channel by the gate dielectric, and locating the back control gate in the base substrate separated from the channel by the insulating layer. In a preferred embodiment of the invention, the isolating layer, also referred to as an insulator or insulating layer, can be a buried oxide layer of a dielectric layer sandwiched between two oxide layers.

The method further comprises operating the front control gate and back control gate jointly by applying a first voltage to the front control gate and a second voltage to the back control gate, wherein the second voltage applied to the back control gate lowers the voltage needed to be applied to the front control gate for programming the cell compared to when no voltage is applied to the back control gate. The second voltage applied to the back control gate can reduce the threshold voltage of the transistor needed to program the cell to be supplied solely by the nominal read voltage Vdd. In a preferred embodiment, the second voltage is positive.

In another embodiment, the method relates to applying a third voltage to the back control gate to perform a cell hold operation to limit leakage from the transistor. The third voltage can be either negative or zero.

In another embodiment, the method relates to applying a fourth voltage to the back control gate to perform a cell read operation, wherein the fourth voltage is positive.

In another embodiment, the front control gate and the back control gate are connected together and a voltage that is identical to the voltage applied to the back control gate is applied to the front control gate.

Another embodiment of the invention relates to a DRAM memory cell comprising a FET transistor on a semiconductor-on-insulator substrate. The FET transistor includes a base substrate, an isolating layer, a thin film of semiconductor material separated from the base substrate by the isolating layer, a channel and two control gates, including a front control gate and a back control gate and a gate dielectric. In this device a programmable cell is formed from the channel, two control gates and gate dielectric with the front control gate arranged on top of the channel and separated from the channel by the gate dielectric, and the back control gate located in the base substrate separated from the channel by the isolating layer.

### BRIEF DESCRIPTION OF THE DRAWINGS

Other aspects, aims and advantages of the present invention will become more apparent from reading the following detailed description of preferred embodiments of the latter, given as non-limiting examples and with reference to the appended drawings in which:

FIG. 1, represents a conventional floating body DRAM cell;

FIG. 2a represents a floating channel DRAM memory cell on SeOI intended for use in the method according to the first aspect of the invention;

FIG. 2b shows a cross section perpendicular to FIG. 2a along the axis IIb-IIb in FIG. 2a representing a floating channel DRAM memory cell on SeOI;

FIG. 3 represents a floating channel DRAM memory cell on SeOI of RCAT type intended for use in the method according to the first aspect of the invention; and

FIGS. 4a-4k illustrate different steps in sequences for forming and isolating a back control gate in the base substrate.

### DETAILED DESCRIPTION OF THE INVENTION

In summary, some of the preferred, but non-limiting, aspects of this method are as follows:

the second voltage is positive;

in a cell hold operation, a third voltage is applied to the back control gate;

the third voltage is negative or zero;

in a cell read operation, a fourth voltage is applied to the back control gate;

the fourth voltage is positive;

the front control gate and the back control gate are connected together and a voltage that is identical to the voltage applied to the back control gate is applied to the front control gate.

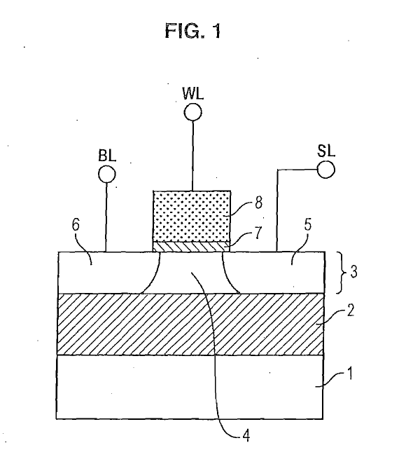

FIG. 1 shows a cross-sectional view of a conventional floating body DRAM cell, also referred to as a floating channel DRAM memory cell. The floating channel DRAM cell is formed in a silicon-on-insulator SOI substrate comprising a thin film of silicon 3 separated form the base substrate 1 by a buried insulating layer 2, which is generally a layer of oxide designated “buried oxide layer” or BOX. A source region 5 and a drain region 6 are formed in the thin film 3 on top of the BOX 2, a floating channel region 4 separating the source and drain regions. A gate dielectric layer 7 and a gate electrode 8 are sequentially deposited on top of the floating channel 4. The drain region 6 is connected to a bit line BL, the source region 5 is connected to a source line SL and the gate electrode 8 is connected to a word line WL.

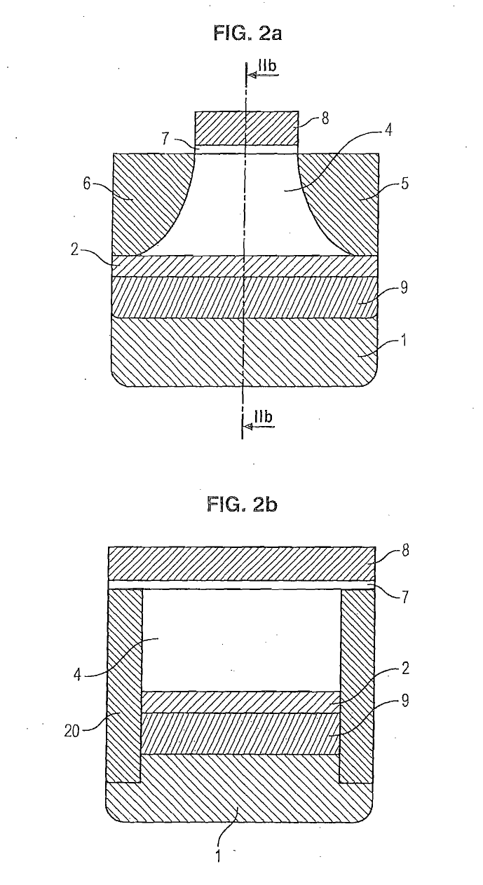

Referring to FIG. 2a, a DRAM memory cell is represented that consists of a floating channel FET transistor on a semiconductor-on-insulator substrate comprising a thin film of semiconductive material separated from a base substrate 1 by an insulating layer 2, typically a buried oxide layer BOX.

The semiconductor-on-insulator substrate is, for example, a silicon-on-insulator SOI substrate.

According to a preferred embodiment, the insulating layer is a layer of SiO₂. According to a more preferred embodiment, the insulating layer comprises a dielectric layer (for example, silicon nitride or Si₃N₄) which can be sandwiched between two layers of SiO₂.

The transistor comprises, in the thin film, a source region 5, a drain region 6 and a floating channel 4 separating the source region from the drain region.

In FIG. 2a, the drain D and the source S are in contact with the buried oxide layer or BOX layer 2 so that the body of the FET transistor is totally isolated from the adjacent cells and consequently floating.

The source S can thus be shared between two adjacent memory cells. Such sharing makes it possible to reduce the surface area occupied by a memory cell.

FIG. 2b shows a cross section perpendicular to FIG. 2a along the axis IIb-IIb in FIG. 2a, representing a floating channel DRAM memory cell on SeOI. While FIG. 2a represents, for example, a cross-sectional view on a line of the memory array, FIG. 2b represents a cross-sectional view along a column of the memory array.

FIG. 2b illustrates the isolation of the body of the transistor (from the transistors along the same column) via lateral isolation trenches 20 (using the STI, shallow trench isolation, technique) extending depthwise from the surface of the substrate at least as far as the insulating layer 2, even passing through this insulating layer so as to separate the wells, which will be described later and in which the back control gates 9 are formed.

It will be understood that the invention is not limited to a fully depleted memory cell but also extends to a partially-depleted memory cell on SeOI. In a manner that is conventionally known per se, it is then also necessary to isolate the cells along a line of the memory array in order to isolate the channels of adjacent cells from one another. This is conventionally done using lateral isolation trenches of STI type extending depthwise from the surface of the substrate at least as far as the insulating layer, or passing through this insulating layer so as to separate the wells, which will be described later and in which the back control gates are formed.

The memory cell also comprises a front control gate 8 extending on the surface of the substrate on top of the channel 4. The front control gate 8 is isolated from the floating channel by means of a gate dielectric layer 7.

The memory cell also comprises a back control gate 9 arranged in the base substrate 1 and separated from the floating channel 4 by the insulating layer 2.

The memory cell thus has two control gates: the front control gate 8 that is conventionally used and the back control gate 9 which is provided by the invention and is notably intended for use jointly with the front control gate to perform a cell programming operation.

As a purely illustrative example, the thickness of the thin film of the semiconductor-on-insulator substrate (body of the transistor) is between 1.5 nm and 50 nm, and the thickness of the insulating layer (BOX) is between 1.5 nm and 50 nm.

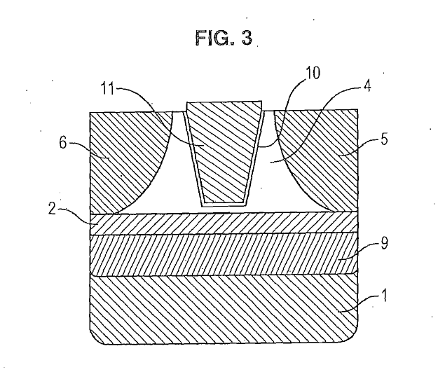

FIG. 3 illustrates another possible embodiment of a fully depleted DRAM memory cell in accordance with the invention, in which the front control gate is not arranged on the surface of the substrate, but is, on the contrary, embedded in the floating channel. The front control gate 11 in this case fills a trench formed in the thickness of the channel 4, a gate dielectric layer 10 being arranged on the walls of the trench so as to isolate the gate 11 from the floating channel 4. A Recessed Channel Array Transistor (RCAT) type transistor is thus defined.

This second embodiment is advantageous in that the apparent width of the floating channel is then increased, making it possible in particular to counteract the undesirable electrical effects known by the acronym SCE (Short Channel Effects).

In the above, the example of a floating channel DRAM cell on SeOI has been taken. The invention does, however, also extend to a DRAM cell on SeOI produced by the combination of a transistor and a capacitor.

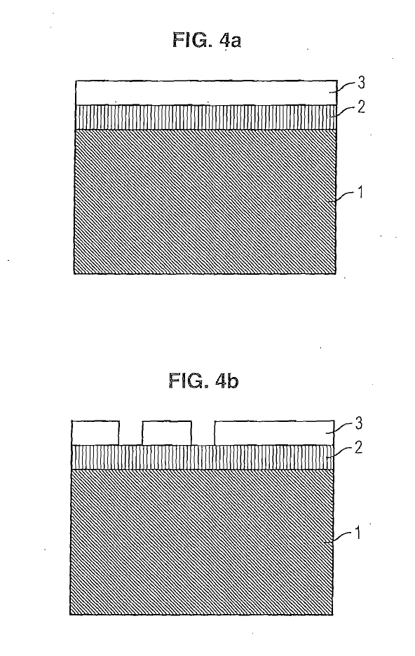

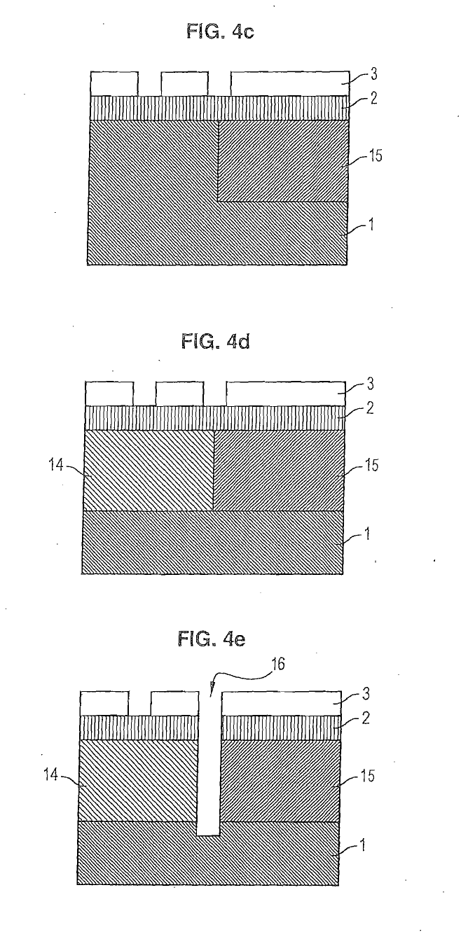

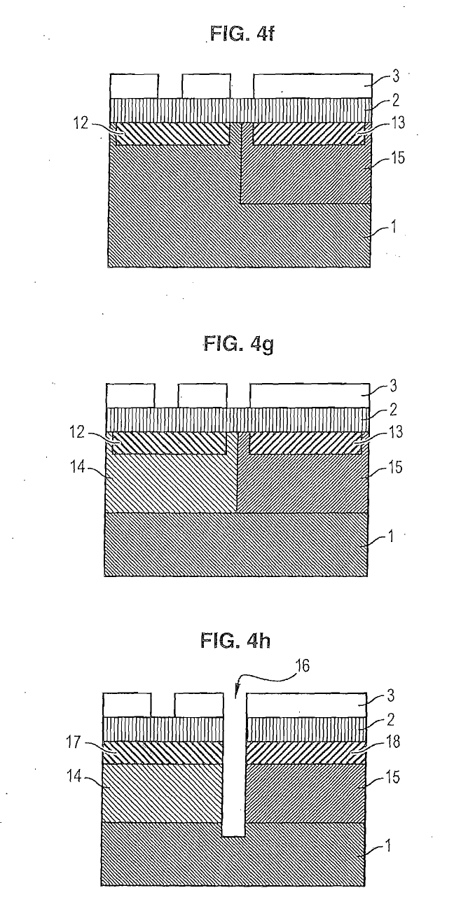

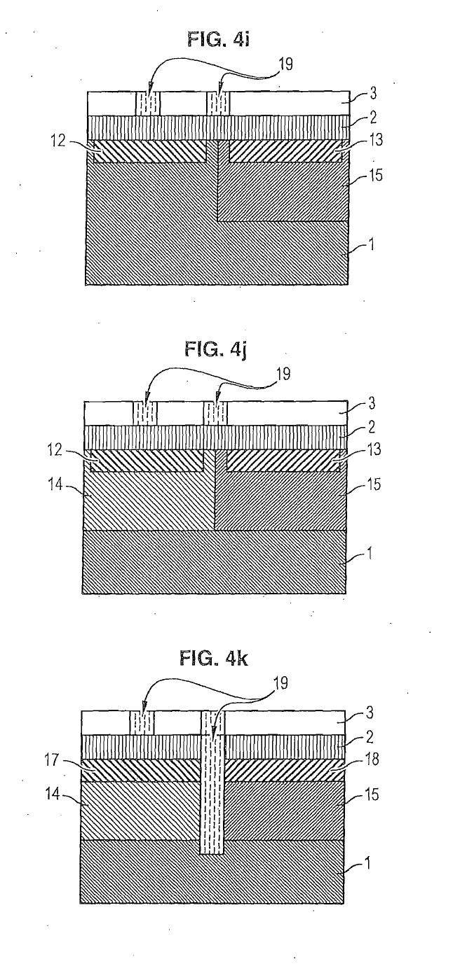

FIGS. 4a-4k illustrate different steps in the sequences for forming and isolating a back control gate in the base substrate. In these figures, the cases of a p-type and n-type back control gate are represented.

FIG. 4a represents an SeOI substrate comprising a thin film of semiconductive material 3 separated from a base substrate 1 by an insulating layer 2.

In a first step, alignment marks are defined in the SeOI substrate so as to provide the necessary alignment in subsequent pattern masking and formation steps (formation of wells, back control gates, isolating structures, etc.).

This first substrate marking step thus consists in forming in the substrate a groove, a trench, a mesa or any other sign (such as a cross for example).

FIG. 4b illustrates to this end the formation of mesas by etching of the surface layer. In order to do this, standard CMOS fabrication processes can be used.

Referring to FIGS. 4c, 4d and 4e, various possible approaches are represented for the formation of wells buried under the insulating layer or BOX 2, the purpose of which is to ultimately ensure that one or more back control gates are isolated from the base substrate 1.

In each of FIGS. 4c, 4d and 4e, the base substrate 1 is doped so as to exhibit, in a top layer or portion of the substrate 1, an n-type conductivity. The doping level is typically between 1×10¹⁵ and 5×10¹⁶ cm⁻³.

In FIG. 4c, a p-type well 15 has been produced, by dopant implantation, below the isolating layer 2 in the n-type base substrate 1. The p-type well 15 is thus isolated from the n-type substrate 1 by a pn junction.

In FIG. 4d, both a p-type well 15 and an n-type well 14 have been produced. The wells 14, 15 are isolated from one another by a pn junction.

In FIG. 4e, both a p-type well 15 and an n-type well 14 have been produced, as in FIG. 4d. An STI-type isolating trench 16 has also been produced, extending depthwise, from the surface of the SeOI substrate, under the insulating layer BOX 2, into the base substrate 1, this trench providing isolation between the wells 14, 15.

The doping level in the wells of FIGS. 4c, 4d and 4e is typically between 5×10¹⁶ and 5×10^{18 cm}⁻³.

It will be noted that the steps needed to fabricate the structures represented in FIGS. 4c, 4d and 4e are based on standard CMOS fabrication processes.

Starting from the structure represented in FIG. 4c (or FIG. 4d and FIG. 4e), a dopant implantation is then implemented in order to form the back control gates 12, 13, 17, 18 under the insulating layer 2 as represented in FIG. 4f (or FIG. 4g and FIG. 4h).

The doping level for the formation of a back control gate is typically between 5×10¹⁸ and 5×10²⁰ cm⁻³.

As represented in FIGS. 4g and 4h, the back control gates 12, 13, 17, 18 are isolated from the base substrate 1 by a well 14, 15 of opposite bias (p-type well 15 for the n-type back control gate 13, 18; n-type well 14 for a p-type back control gate 12, 17).

In the case of FIG. 4f, a well has been produced only for a single back control gate bias (p-type well 13 isolates an n-type back control gate 13, while a p-type back control gate 12 is arranged directly in the n-biased base substrate 1).

It will be noted that, as a general rule, the well voltage is chosen so that the diode created by the electrical node between the back control gate and the well is always reversed, the diode then isolating the back control gate from the well and from anything that it might contain (other back control gates in particular).

According to a first embodiment represented in FIG. 4h, the back control gate 17, 18 extends under the insulating layer 2 across the entire width of the well 14, 15. In this particular case, the isolating trench 16 is used to isolate the back control gates 17, 18 from one another.

According to another embodiment represented in FIG. 4g, the back control gate 12, 13 is located so as to extend only over a portion of the width of the well 14, 15. It will be noted that an isolating trench can also be provided when the back control gate is localized by thus contributing to the isolation of the wells.

According to a variant embodiment that is not represented, a second isolating layer, arranged in the base substrate below the BOX isolating layer, can contribute, wholly or partly, to the isolation of a back control gate from the base substrate.

Starting from the structure represented in FIG. 4f (or FIG. 4g or 4h), the mesas and, where appropriate, the isolating trenches are then filled by the deposition of a dielectric material. This filling implements standard side wall passivation, filling and surface planarization processing operations.

One or more transistors (of the same type) can then be formed in each of the regions of the thin film 3 delimited by the insulating regions 19 formed by the duly deposited dielectric, as shown in FIG. 4i (or FIG. 4j or 4k).

In the context of the invention, the back control gate is used to dynamically modify the effective threshold voltage of the transistor. More particularly, the voltage that is applied to the back control gate is modulated according to the type of cell control operations (programming, erase, read, hold).

A transistor whose channel has an n-type conductivity and a back control gate of p-type conductivity (the back control gate is then said to have a work function) has a very high threshold voltage. This threshold voltage can then be reduced by applying a positive voltage to the back control gate.

A transistor whose channel has an n-type conductivity and a back control gate of n-conductivity (the back control gate is then said to have no work function) has a nominal threshold voltage that can be reduced by applying a positive voltage to the back control gate.

This variation of the threshold voltage of the transistor via the back control gate can be formulated according to Vth=Vt0−αVBG, in which Vth represents the threshold voltage of the transistor, VBG the voltage applied to the back control gate, Vt0 the nominal threshold voltage (which can also be offset by the work function depending on whether an n- or p-type or metal back control gate is used), and a a coefficient linked to the architecture of the transistor.

As presented in the thesis entitled “Architectures innovantes de mémoire non-volative embarquée sur film mince de silicium” (Innovative non-volatile memory architectures embedded in a thin silicon film), defended by Germain Bossu in June 2009 at the University of Provence Aix Marseille I, the coefficient a can in prticular be approximated according to

$$α = \frac{3 \cdot {t}_{ox 1}}{{t}_{Si} + 3 \cdot {t}_{ox 2}} ,$$

in which tₒₓ₁ denotes the thickness of the gate dielectric layer separating the front control gate from the channel, tₒₓ₂ denotes the thickness of the insulating layer separating the back control gate from the channel and tₛᵢ denotes the thickness of the thin film.

It will therefore be understood that the type of doping of the back control gate associated with a transistor offsets or does not offset the nominal threshold voltage, and that the bias of the back control gate can be used to adjust the threshold voltage.

In the context of the invention, the bias of the back control gate 6 is preferentially chosen so that the back control gate does not have any work function. This bias must thus be of the same type as the FET transistor (in other words, an n-type bias for an n-type transistor, a p-type bias for a p-type transistor). The invention does, however, also extend to a back gate having a working voltage (bias opposite to that of the FET transistor).

Moreover, the invention is of course not limited to an n-type transistor, but also extends to a p-type transistor.

Returning to the general case of a back control gate, a positive voltage applied to the back control gate reduces the effective threshold voltage of the transistor.

The effective threshold voltage can also be increased via a negative voltage applied to the back control gate, thereby reducing the leakage currents, advantageously in an overall inactive state of the circuit.

In the context of the invention, the back control gate associated with a transistor of an SeOI DRAM cell is used dynamically: the voltage applied to it is effectively modulated according to the type of cell control operations (programming, erase, read, hold or retain).

The invention thus proposes jointly using the front control gate and the back control gate in a cell programming operation, by applying a first voltage to the front control gate and a second voltage to the back control gate, said first voltage being lower in amplitude than the voltage needed to program the cell when no voltage is applied to the back control gate.

The second voltage is positive, and preferably equal to the nominal power supply voltage Vdd in the case of an n-channel transistor.

In the case of a cell with p-channel transistor, operation remains symmetrical to the case of an n-channel transistor. The voltages applied are then referenced relative to Vdd and are negative relative to that reference, thus tending toward the zero voltage.

The example of an n-channel transistor is described below.

According to a preferred embodiment, the back control gate voltage is positive for programming and zero for the other operations.

In programming, the application of a positive voltage to the back control gate effectively makes it possible to reduce the threshold voltage of the transistor. The front control gate can then be supplied solely by the nominal read voltage Vdd. The programming voltages can thus be lowered, which considerably helps in the design of peripheral circuits (the word line control circuits no longer need to deliver high voltages, so that the need for circuits generating the overvoltage is eliminated) and reinforces the reliability of the cell and of the circuit in general.

Inasmuch as the stresses on the transistor are lowered, it is also possible to use smaller transistors.

According to a variant embodiment, a third voltage, wherein the the third voltage is different from the second voltage, can be applied to the back control gate in a holding operation, in order to allow a better retention of the charges in the floating channel. A zero or slightly negative voltage (a voltage close to Vdd in the case of a p-channel transistor) applied to the back control gate in holding operations makes it possible in particular to limit the leaks from the transistor.

Bearing in mind that, in the interests of simplicity, it is preferable to work with back control gate voltages equal to simple values (typically 0V, VDD, and possibly VDD/2), which require none or few circuits (that consume energy) to be available.

It will be remembered, however, that, in the case where the back control gate effect on the threshold voltage of the transistor does not have the desired amplitude, the voltage applied to the back control gate can still be modified to compensate for a “bad” ratio of thicknesses of the thin film, of the insulating layer, and of the gate dielectric layer, by using back control gate voltages different from the simple values mentioned hereinabove.

According to yet another variant, a fourth voltage, notably a positive voltage, is applied to the back control gate in a read operation. A read operation is, in effect, generally followed by a restore, that is to say a reprogramming. The application of a positive voltage to the back control gate in a read operation is then advantageous in that it makes it possible to reduce the voltages that then have to be applied to the front control gate.

It will have been understood from the forgoing that the invention makes it possible to advantageously use a memory cell that has an individualized back control gate. At the very least, only the cells arranged on one and the same line or one and the same column of a memory array share the same back control gate. A back gate line can thus be coupled to the back control gate of each of the cells along a line or a column.

In a manner generally known to those in the art, a word line is coupled to the front control gate of each of the cells along a column of the memory array.

Provision is preferentially made for the back gate line to extend in parallel with the word line (the back control gate effectively assisting the front control gate in programming).

It is also possible to provide for the front control gate and the back control gate of a memory cell to be connected together which makes it possible to reduce the number of decoders needed. In particular, the word line of a column of a memory array can be linked to the back gate line parallel to it.

What is claimed is:

1. A method of controlling a DRAM memory cell comprising a FET transistor on a semiconductor-on-insulator substrate comprising:
providing a FET transistor that includes a base substrate, an isolating layer, a thin film of semiconductor material separated from the base substrate by the isolating layer, a channel and two control gates, including a front control gate and a back control gate and a gate dielectric; and
forming a programmable cell from the channel, two control gates and gate dielectric by:
arranging the front control gate on top of the channel and separated from the channel by the gate dielectric, and
locating the back control gate in the base substrate separated from the channel by the isolating layer.

2. The method according to claim 1, wherein the insulator is a buried oxide layer.

3. The method according to claim 2, wherein the insulating layer comprises a dielectric layer sandwiched between oxide layers.

4. The method of claim 1, which further comprises jointly operating the front control gate and back control gate by applying a first voltage to the front control gate and a second voltage to the back control gate, wherein the second voltage applied to the back control gate lowers the voltage needed to be applied to the front control gate for programming the cell compared to when no voltage is applied to the back control gate.

5. The method according to claim 4, wherein the second voltage is positive.

6. The method according to claim 4, which further comprises applying a third voltage to the back control gate to perform a cell hold operation to limit leakage from the transistor.

7. The method according to claim 6, wherein the third voltage is either negative or zero.

8. The method according to claim 6, which fBurther comprises applying a fourth voltage to the back control gate to perform a cell read operation.

9. The method according to claim 8, wherein the fourth voltage is positive.

10. The method according claim 1, which further comprises connecting the front and back control gates together and applying to the front control gate a voltage that is identical to the voltage applied to the back control gate.

11. A DRAM memory cell comprising a FET transistor on a semiconductor-on-insulator substrate, with the FET transistor comprising a base substrate, an isolating layer, a thin film of semiconductor material separated from the base substrate by the isolating layer, a channel and two control gates, including a front control gate and a back control gate and a gate dielectric; and a programmable cell formed from the channel, two control gates and gate dielectric with the front control gate arranged on top of the channel and separated from the channel by the gate dielectric, and the back control gate located in the base substrate separated from the channel by the isolating layer.

12. The cell according to claim 10, wherein the insulator is a buried oxide layer.

13. The cell according to claim 10, wherein the insulating layer comprises a dielectric layer sandwiched between oxide layers.
